(19) United States
(12) Patent Application Publication
(10) Pub. No.: US 2024/0321917 A1
(43) Pub. Date: Sep. 26, 2024

(54) IMAGING DEVICE

(71) Applicant: SONY SEMICONDUCTOR SOLUTIONS CORPORATION, KANAGAWA (JP)

(72) Inventor: KAITO YOKOCHI, KANAGAWA (JP)

(21) Appl. No.: 18/579,741

(22) PCT Filed: Jul. 22, 2022
(86) PCT No.: PCT/JP2022/028471

§ 371 Date: Jan. 16, 2024

(30) Foreign Application Priority Data
Aug. 6, 2021 (JP) 2021-129694

(51) Int. Cl. H01L 27/146

(52) U.S. Cl. CPC H01L 27/14625; H01L 27/14645

(57) ABSTRACT

An imaging device according to one embodiment of the present disclosure includes a first filter having a first refractive index for entering light, a first photoelectric conversion section that performs photoelectric conversion on light transmitted through the first filter, a second filter that has a second refractive index lower than the first refractive index for entering light and is adjacent to the first filter, a second photoelectric conversion section that performs photoelectric conversion on light transmitted through the second filter, a first medium that is provided on an opposite side of the first photoelectric conversion section as viewed from the first filter and has a third refractive index for entering light, and a second medium that is provided on an opposite side of the second photoelectric conversion section as viewed from the second filter and has a fourth refractive index higher than the third refractive index for entering light.

### TECHNICAL FIELD

The present disclosure relates to an imaging device.

### BACKGROUND ART

An imaging device in which each pixel is separated by a device separator embedded in an insulating film has been proposed (PTL 1).

### CITATION LIST

### Patent Literature

PTL 1: Japanese Unexamined Patent Application Publication No. 2013-175494

### SUMMARY OF THE INVENTION

It is expected that an imaging device receives entering light efficiently.

It is desired to provide an imaging device able to receive light efficiently.

An imaging device as one embodiment of the present disclosure includes a first filter having a first refractive index for entering light, a first photoelectric conversion section that performs photoelectric conversion on light transmitted through the first filter, a second filter that has a second refractive index lower than the first refractive index for entering light and is adjacent to the first filter, a second photoelectric conversion section that performs photoelectric conversion on light transmitted through the second filter, a first medium that is provided on an opposite side of the first photoelectric conversion section as viewed from the first filter and has a third refractive index for entering light, and a second medium that is provided on an opposite side of the second photoelectric conversion section as viewed from the second filter and has a fourth refractive index higher than the third refractive index for entering light.

### BRIEF DESCRIPTION OF DRAWINGS

FIG. 1 is a block diagram illustrating an example of an overall configuration of an imaging device according to an embodiment of the present disclosure.

FIG. 2 illustrates an example of a planar configuration of the imaging device according to an embodiment of the present disclosure.

FIG. 3A illustrates a configuration example of a portion of the imaging device according to an embodiment of the present disclosure.

FIG. 3B illustrates a configuration example of a portion of the imaging device according to an embodiment of the present disclosure.

FIG. 3C illustrates a configuration example of a portion of the imaging device according to an embodiment of the present disclosure.

FIG. 4 illustrates an example of a wavelength dependence of a refractive index of a color filter.

FIG. 5A illustrates an example of a planar configuration of the imaging device according to an embodiment of the present disclosure.

FIG. 5B illustrates an example of a cross-sectional configuration of the imaging device according to an embodiment of the present disclosure.

FIG. 5C illustrates an example of a cross-sectional configuration of the imaging device according to an embodiment of the present disclosure.

FIG. 6A illustrates an example of a planar configuration of the imaging device according to an embodiment of the present disclosure.

FIG. 6B illustrates an example of a cross-sectional configuration of the imaging device according to an embodiment of the present disclosure.

FIG. 6C illustrates an example of a cross-sectional configuration of the imaging device according to an embodiment of the present disclosure.

FIG. 7A illustrates an example of a planar configuration of the imaging device according to an embodiment of the present disclosure.

FIG. 7B illustrates an example of a cross-sectional configuration of the imaging device according to an embodiment of the present disclosure.

FIG. 7C illustrates an example of a cross-sectional configuration of the imaging device according to an embodiment of the present disclosure.

FIG. 8A illustrates a configuration example of an imaging device according to Modification Example 1 of the present disclosure.

FIG. 8B illustrates a configuration example of the imaging device according to Modification Example 1 of the present disclosure.

FIG. 9A illustrates a configuration example of an imaging device according to Modification Example 2 of the present disclosure.

FIG. 9B illustrates a configuration example of the imaging device according to Modification Example 2 of the present disclosure.

FIG. 10A illustrates a configuration example of an imaging device according to Modification Example 3 of the present disclosure.

FIG. 10B illustrates a configuration example of the imaging device according to Modification Example 3 of the present disclosure.

FIG. 11A illustrates a configuration example of an imaging device according to Modification Example 4 of the present disclosure.

FIG. 11B illustrates a configuration example of the imaging device according to Modification Example 4 of the present disclosure.

FIG. 12A illustrates a configuration example of an imaging device according to Modification Example 5 of the present disclosure.

FIG. 12B illustrates a configuration example of the imaging device according to Modification Example 5 of the present disclosure.

FIG. 13 is a block diagram illustrating a configuration example of an electronic apparatus including an imaging device.

FIG. 14 is a block diagram depicting an example of schematic configuration of a vehicle control system.

FIG. 15 is a diagram of assistance in explaining an example of installation positions of an outside-vehicle information detecting section and an imaging section.

FIG. 16 is a view depicting an example of a schematic configuration of an endoscopic surgery system.

FIG. 17 is a block diagram depicting an example of a functional configuration of a camera head and a camera control unit (CCU).

### MODES FOR CARRYING OUT THE INVENTION

In the following, some embodiments of the present disclosure will be described in detail with reference to the drawings. It is to be noted that the description will be given in the following order.
1. First Embodiment
2. Modification Examples
2-1. Modification Example 1
2-2. Modification Example 2
2-3. Modification Example 3
2-4. Modification Example 4
2-5. Modification Example 5
3. Application Example
4. Practical Applications

### 1. First Embodiment

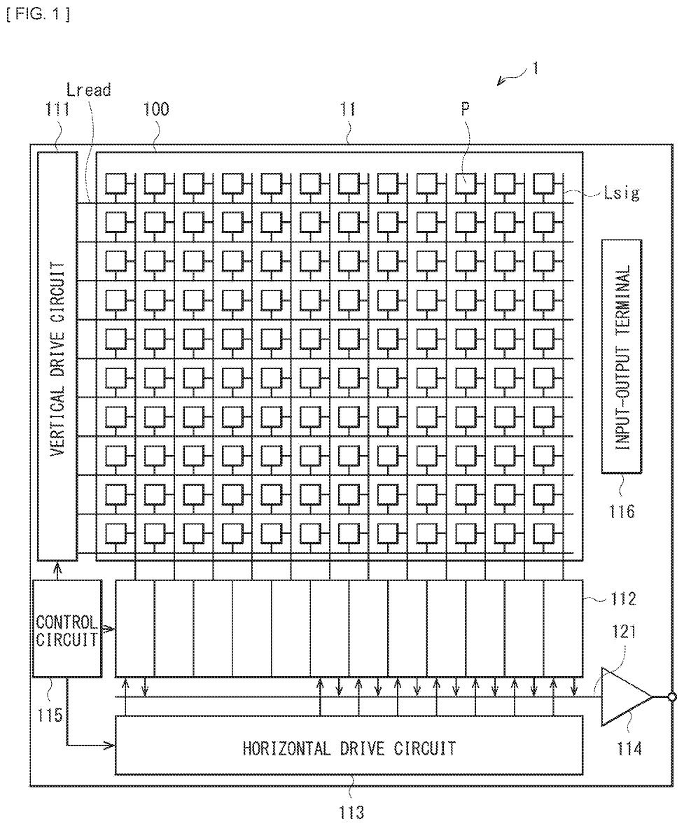

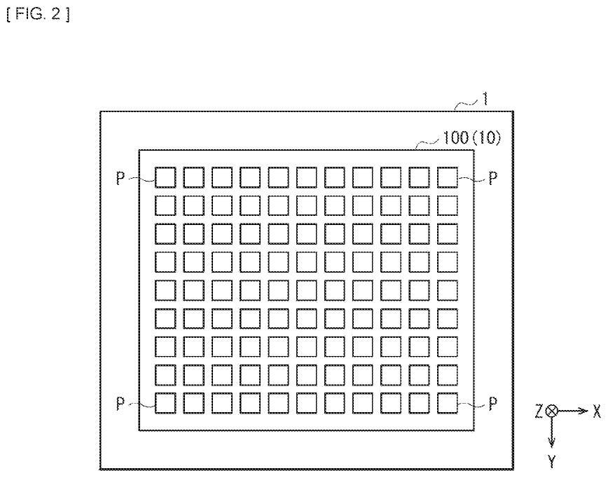

FIG. 1 is a block diagram illustrating an example of an overall configuration of an imaging device (imaging device 1) according to an embodiment of the present disclosure. FIG. 2 illustrates an example of a planar configuration of the imaging device 1. For example, the imaging device 1 is a CMOS (Complementary Metal Oxide Semiconductor) image sensor.

In the imaging device 1, pixels P each including a photoelectric conversion section are arranged in a matrix. As illustrated in FIG. 2, the imaging device 1 includes, as an imaging area, a region (pixel section 100) in which a plurality of pixels P is arranged two-dimensionally in a matrix. The imaging device 1 is applicable to an electronic apparatus such as a digital still camera or a video camera. It is to be noted that as illustrated in FIG. 2, an entering direction of light from a subject is assumed as a Z-axis direction, a crosswise direction on paper orthogonal to the Z-axis direction is assumed as an X-axis direction, and a lengthwise direction on the paper orthogonal to the Z- and X-axes is assumed as a Y-axis direction. In the subsequent drawings, a direction will be indicated with reference to arrow direction in FIG. 2 in some cases.

### [Schematic Configuration of Imaging Device]

The imaging device 1 captures entering light (image light) from a subject via an optical lens system (not illustrated). The imaging device 1 captures an image of the subject. The imaging device 1 converts a quantity of the entering light, which is formed into an image on an imaging surface, into an electrical signal on a pixel-by-pixel basis and outputs the electrical signal as a pixel signal. The imaging device 1 includes a pixel section 100 as the imaging area. In addition, for example, the imaging device 1 includes a vertical drive circuit 111, a column signal processing circuit 112, a horizontal drive circuit 113, an output circuit 114, a control circuit 115, and an input-output terminal 116 in a peripheral region of the pixel section 100.

In the pixel section 100, a plurality of pixels P is arranged two-dimensionally in a matrix. In the pixel section 100, there are provided a plurality of pixel rows each including a plurality of pixels P arranged in a horizontal direction (crosswise direction on paper) and a plurality of columns each including a plurality of pixels P arranged in a vertical direction (lengthwise direction on paper).

In the pixel section 100, for example, a pixel drive line Lread (row selection line and reset control line) is provided for each pixel row, and a vertical signal line Lsig is provided for each pixel column. The pixel drive line Lread transmits a drive signal to read out a signal from a pixel. The pixel drive line Lread has one end coupled to an output terminal corresponding to each pixel row in the vertical drive circuit 111.

The vertical drive circuit 111 includes a shift register, an address decoder, and the like. The vertical drive circuit 111 is a pixel drive section that drives each pixel P in the pixel section 100, for example, on a row-by-row basis. The column signal processing circuit 112 includes an amplifier, a horizontal selection switch, and the like that are provided for each vertical signal line Lsig. The signal outputted from each pixel P in a pixel row selectively scanned by the vertical drive circuit 111 is supplied to the column signal processing circuit 112 through the vertical signal line Lsig.

The horizontal drive circuit 113 includes a shift register, an address decoder, and the like, and sequentially drives, while scanning, each horizontal selection switch of the column signal processing circuit 112. As a result of this selective scanning by this horizontal drive circuit 113, the signal of each pixel transmitted through each vertical signal line Lsig is sequentially outputted to the horizontal signal line 121, to be transmitted to an outside of a semiconductor substrate 11 through the horizontal signal line 121.

The output circuit 114 performs signal processing on the signal that is supplied sequentially from each column signal processing circuit 112 via the horizontal signal line 121, and outputs the signal. For example, the output circuit 114 performs only buffering in some cases, or performs black level adjustment, column variation correction, various digital signal processing, and the like in other cases.

A circuit portion including the vertical drive circuit 111, the column signal processing circuit 112, the horizontal drive circuit 113, the horizontal signal line 121, and the output circuit 114 may be formed on the semiconductor substrate 11 or may be provided in an external control IC. In addition, a portion including those circuits may also be formed on another substrate coupled by cable or the like.

The control circuit 115 receives a clock provided from outside the semiconductor substrate 11, data commanding an operation mode, or the like, and also outputs data such as internal information of the imaging device 1. Furthermore, the control circuit 115 includes a timing generator that generates various timing signals, and performs drive control on a peripheral circuit such as the vertical drive circuit 111, the column signal processing circuit 112, the horizontal drive circuit 113, and the like on the basis of the various timing signals generated by the timing generator. The input-output terminal 116 exchanges a signal with an outside.

### [Pixel Configuration]

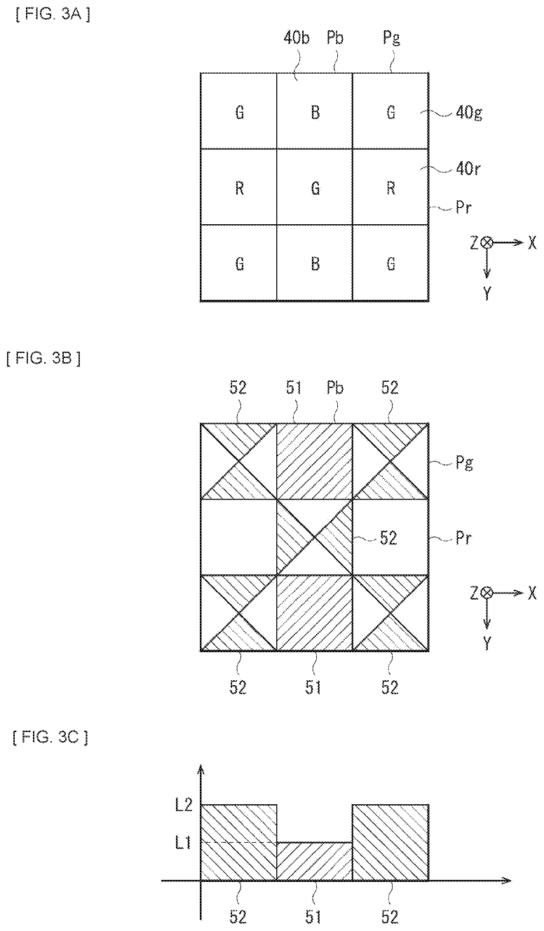

FIG. 3A illustrates a planar configuration of color filters 40r, 40g, and 40b in the imaging device 1. FIG. 3B illustrates a planar configuration of an upper layer of the color filters 40r, 40g, and 40b illustrated in FIG. 3A.

The color filters 40r, 40g, and 40b selectively transmit light having a specific wavelength range out of entering light. The imaging device 1 includes a pixel Pr including the color filter 40r that transmits red (R) light, a pixel Pg including the color filter 40g that transmits green (G) light, and a pixel Pb including the color filter 40b that transmits blue (B) light. In the pixel section 100 of the imaging device 1, the pixel Pr, the pixel Pg, and the pixel Pb are arranged in accordance with Bayer arrangement. The pixel Pr, the pixel Pg, and the pixel Pb generate an R component pixel signal, a G component pixel signal, and a B component pixel signal, respectively. This allows the imaging device 1 to obtain RGB pixel signals.

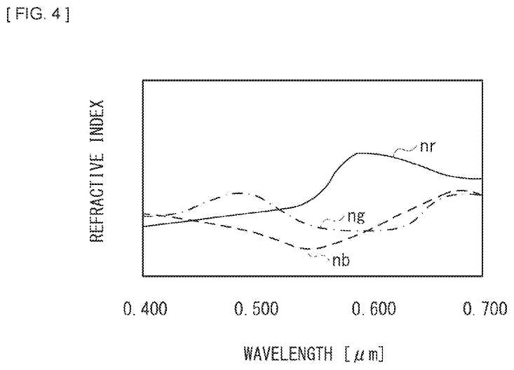

FIG. 4 illustrates an example of a wavelength dependence of a refractive index of a color filter 40. In FIG. 4, a solid line nr illustrates a refractive index of the red (R) color filter 40r. An alternate long and short dash line ng illustrates a refractive index of the green (G) color filter 40g, and a dash line nb illustrates a refractive index of the blue (B) color filter 40b.

At a blue wavelength, for example, at a wavelength near 460 nm, the blue color filter 40b has a refractive index lower than the refractive index of the green color filter 40g. Thus, in a case where light having a blue wavelength (for example, 460 nm) enters a region in which the blue color filter 40b and the green color filter 40g are adjacent to each other, the light tends to proceed toward the green color filter 40g having a relatively high refractive index.

In addition, at a green wavelength, for example, at a wavelength near 530 nm, the green color filter 40g has a refractive index lower than the refractive index of the red color filter 40r. Thus, in a case where light having a green wavelength (for example, 530 nm) enters a region in which the green color filter 40g and the red color filter 40r are adjacent to each other, the light tends to proceed toward the red color filter 40r having a relatively high refractive index. It is to be noted that at a red wavelength, for example, at a wavelength near 630 nm, the red color filter 40r has a refractive index higher than the refractive indices of the green color filter 40g and blue color filter 40b.

Then, in the imaging device 1, a medium having a refractive index higher than the refractive index of the medium on the green color filter 40g is provided on a portion adjacent to the green color filter 40g, of the blue color filter 40b. In addition, a medium having a refractive index higher than the refractive index of the medium on the red color filter 40r is provided on a portion adjacent to the red color filter 40r, of the green color filter 40g. In the example illustrated in FIG. 3B, a first light guiding member 51 is provided on the blue color filter 40b, and a second light guiding member 52 is provided on the green color filter 40g.

The first light guiding member 51 is provided to cover at least the portion adjacent to the green color filter 40g, of the blue color filter 40b. In the example illustrated in FIG. 3B, the first light guiding member 51 is formed to cover an entire surface of the blue color filter 40b. The first light guiding member 51 has a refractive index higher than a refractive index of a portion in which the second light guiding member 52 is not present, on the adjacent green color filter 40g.

The second light guiding member 52 is provided to cover at least the portion adjacent to the red color filter 40r, of the green color filter 40g. As a material to be included in the first light guiding member 51 and the second light guiding member 52, for example, it is possible to give silicon nitride (SiN), titanium oxide (TiO), silicon oxide (SiO), tantalum oxide (TaO), hafnium oxide (HfO), amorphous silicon (a-Si), polysilicon (Poly-Si), or the like. The first light guiding member 51 and the second light guiding member 52 may each include a different material.

FIG. 3C illustrates an example of a thickness (film thickness) of the first light guiding member 51 and the second light guiding member 52. A film thickness L2 of the second light guiding member 52 is greater than a film thickness L1 of the first light guiding member 51. The film thickness, shape, refractive index, and the like of the first light guiding member 51 and the second light guiding member 52 are determined to allow light entering the first light guiding member 51 and the second light guiding member 52 to proceed in a desired direction. For example, the film thickness of the first light guiding member 51 is determined in accordance with a difference in refractive index between the blue and green color filters 40 at a wavelength of 460 nm. In addition, for example, the film thickness of the second light guiding member 52 is determined in accordance with a difference in refractive index between the green and red color filters 40 at a wavelength of 530 nm.

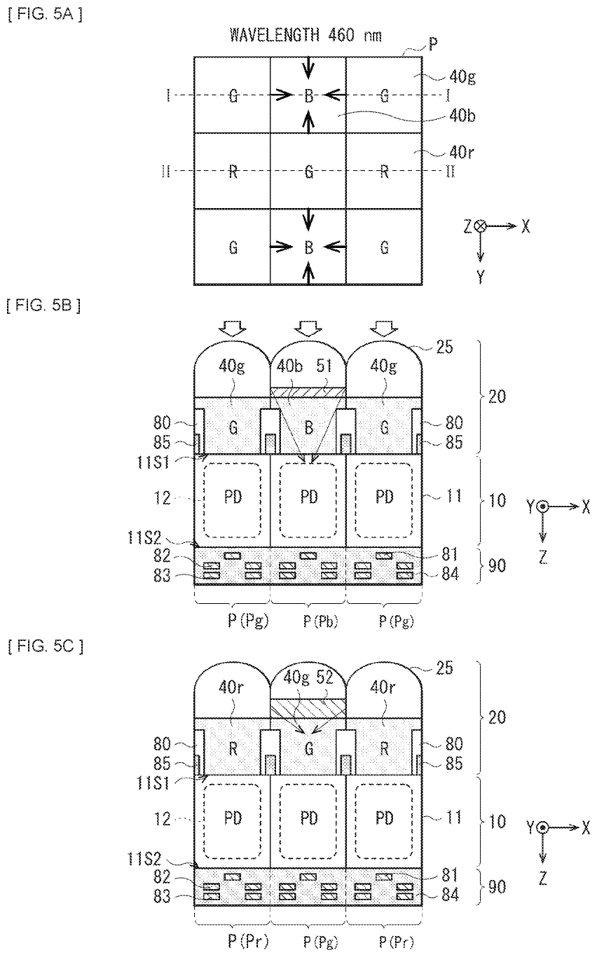

FIGS. 5A to 5C illustrate a configuration example of the imaging device 1 including the first light guiding member 51 and the second light guiding member 52. FIG. 5B illustrates a cross-sectional configuration in a line I-I direction illustrated in FIG. 5A. FIG. 5C illustrates a cross-sectional configuration in a line II-II direction illustrated in FIG. 5A. As illustrated in FIG. 5B or FIG. 5C, for example, the imaging device 1 has a configuration in which a light receiving section 10, a light guiding section 20, and a multilayer wiring layer 90 are laminated.

The light receiving section 10 includes the semiconductor substrate 11 having a first surface 11S1 and a second surface 11S2 opposed to each other. The light guiding section 20 is provided on the first surface 11S1 side of the semiconductor substrate 11, and the multilayer wiring layer 90 is provided on the second surface 11S2 side of the semiconductor substrate 11. It can also be said that the light guiding section 20 is provided on the side that light from a subject enters and the multilayer wiring layer 90 is provided on the opposite side of the side that the light enters. The imaging device 1 is what is called a back-illuminated imaging device.

For example, the semiconductor substrate 11 includes a silicon substrate. The photoelectric conversion section 12 is a photo diode (PD), for example, and has a pn junction in a predetermined region in the semiconductor substrate 11. In the semiconductor substrate 11, a plurality of photoelectric conversion sections 12 is embeddingly formed. In the light receiving section 10, the plurality of photoelectric conversion sections 12 is provided along the first surface 11S1 and the second surface 11S2 of the semiconductor substrate 11.

For example, the multilayer wiring layer 90 has a configuration in which a plurality of wiring layers 81, 82, and 83 is laminated with an interlayer insulating layer 84 in between. In the semiconductor substrate 11 and the multilayer wiring layer 90, a circuit (for example, a transfer transistor, a reset transistor, an amplifying transistor, or the like) to read out a pixel signal based on an electric charge generated by the photoelectric conversion section 12 is formed. In addition, in the semiconductor substrate 11 and the multilayer wiring layer 90, for example, the above described vertical drive circuit 111, column signal processing circuit 112, horizontal drive circuit 113, output circuit 114, control circuit 115, input-output terminal 116, and the like are formed.

For example, the wiring layers 81, 82, and 83 are formed using aluminum (Al), copper (Cu), tungsten (W), or the like. Other than this, the wiring layers 81, 82, and 83 may be formed using polysilicon (Poly-Si). The interlayer insulating layer 84 includes, for example, a single layer film including one type from among silicon oxide (SiOx), TEOS, silicon nitride (SiNx), silicon oxynitride (SiOxNy), and the like, or a multilayer film including two or more types from these.

The light guiding section 20 includes a lens section (on-chip lens) 25 that performs light collection, the first light guiding member 51, the second light guiding member 52, and the color filter 40, and guides entering light toward the light receiving section 10 side. The light guiding section 20 is laminated on the light receiving section 10 in a thickness direction orthogonal to the first surface 11S1 of the semiconductor substrate 11.

At a boundary between adjacent pixels P, a waveguide 80 and a light-shielding section 85 to block light are provided. The waveguide 80 guides entering light to the light-shielding section 85. For example, the light-shielding section 85 includes a light-absorbing material and absorbs entering light.

As illustrated in FIG. 5B, the first light guiding member 51 is provided between the lens section 25 and the blue color filter 40b. The first light guiding member 51 is located on the blue color filter 40b. The first light guiding member 51 has a refractive index higher than a refractive index of a surrounding medium. As the medium surrounding the first light guiding member 51, it is possible to give silicon oxide (SiOx), air (void), or the like. In the example illustrated in FIG. 5B, the first light guiding member 51 includes a material having a refractive index higher than a refractive index of the lens section 25 in the pixel Pg that is adjacent in the X-axis direction.

The first light guiding member 51 provides phase delay to entering light due to a difference in refractive index between the first light guiding member 51 and the surrounding medium. In the first light guiding member 51, a propagation direction of entering light changes due to an occurrence of phase delay. This allows the first light guiding member 51 to change a travelling direction of the light. It can also be said that the first light guiding member 51 is a deflection section (deflection element) 51 that deflects light.

As illustrated in FIG. 5C, the second light guiding member 52 is provided between the lens section 25 and the green color filter 40g. The second light guiding member 52 is located on the green color filter 40g. The second light guiding member 52 has a refractive index higher than a refractive index of the surrounding medium. As the medium surrounding the second light guiding member 52, it is possible to give silicon oxide (SiOx), air (void), or the like. In the example illustrated in FIG. 5C, the second light guiding member 52 includes a material having a refractive index higher than the refractive index of the lens section 25 in the pixel Pr that is adjacent in the X-axis direction.

The second light guiding member 52 provides phase delay to entering light due to a difference in refractive index between the second light guiding member 52 and the surrounding medium. In the second light guide 52, the propagation direction of entering light changes due to an occurrence of phase delay. This allows the second light guiding member 52 to change the traveling direction of the light. It can also be said that the second light guiding member 52 is a deflection section (deflection element) 52 that deflects light.

With reference to FIGS. 5A to 5C, a case where light having a blue wavelength range of 460 nm enters will be described. In FIG. 5B, the light having a blue wavelength, which enters the first light guiding member 51 via the lens section 25 from above, proceeds toward the color filter 40b in the pixel Pb out of the pixels Pg and Pb adjacent to each other. As indicated by arrows in FIG. 5B, the light entering an end of the first light guiding member 51 is also deflected by the first light guiding member 51 to proceed toward the color filter 40b and the photoelectric conversion section 12 in the pixel Pb. As indicated by arrows in FIG. 5A, this makes it possible for the first light guiding member 51 to collect the entering light having a blue wavelength at the color filter 40b and the photoelectric conversion section 12 in the pixel Pb. Compared to a case of the imaging device 1 that does not include the first light guiding member 51, the photoelectric conversion section 12 in the pixel Pb is able to efficiently receive light having a blue wavelength and perform photoelectric conversion.

In FIG. 5C, the light having a blue wavelength, which enters the second light guiding member 52 via the lens section 25 from above, proceeds toward the color filter 40g in the pixel Pg out of the pixels Pr and Pg adjacent to each other. As indicated by arrows in FIG. 5C, the light entering an end of the second light guiding member 52 is also deflected by the second light guiding member 52 to proceed toward the color filter 40g in the pixel Pg. The light having a blue wavelength, which enters the green color filter 40g, is absorbed by the green color filter 40g. This makes it possible to prevent unnecessary light from leaking into a surrounding portion, suppressing generation of color mixing.

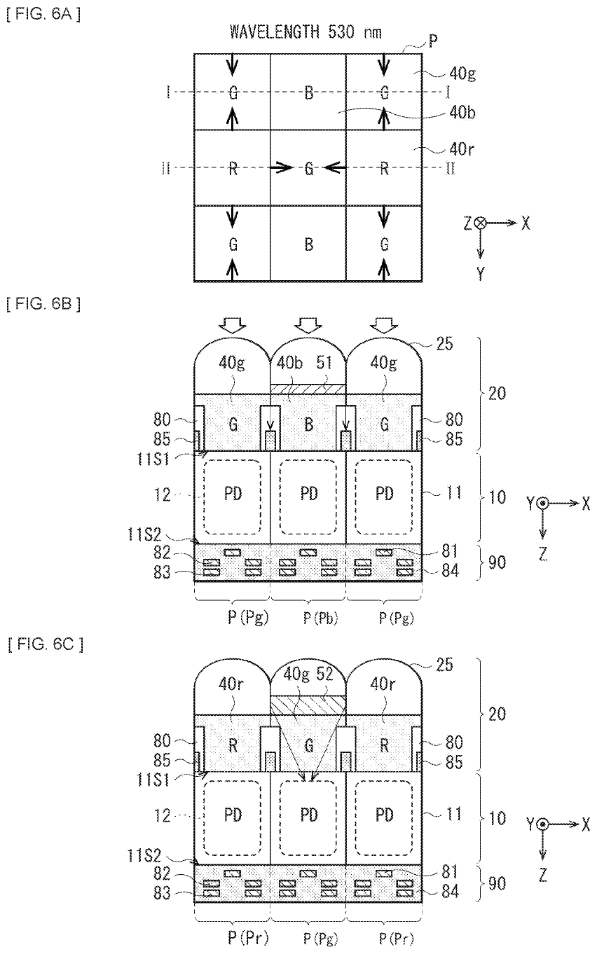

Next, with reference to FIGS. 6A to 6C, a case where light having a green wavelength range of 530 nm enters will be described. FIG. 6B illustrates a cross-sectional configuration in a line I-I direction illustrated in FIG. 6A. FIG. 6C illustrates a cross-sectional configuration in a line II-II direction illustrated in FIG. 6A. In FIG. 6B, the light having a green wavelength, which enters the first light guiding member 51 via the lens section 25 from above, proceeds toward the color filter 40b or the light-shielding section 85 in the pixel Pb, to be absorbed by the blue color filter 40b or the light-shielding section 85. This makes it possible to prevent unnecessary light from leaking into a surrounding portion, suppressing generation of color mixing.

In FIG. 6C, the light having a green wavelength, which enters the second light guiding member 52 through the lens section 25, proceeds toward the color filter 40g in the pixel Pg out of the pixels Pr and Pg adjacent to each other. As indicated by arrows in FIG. 6C, the light entering an end of the second light guiding member 52 is also deflected by the second light guiding member 52 to proceed toward the color filter 40g and the photoelectric conversion section 12 in the pixel Pg. As indicated by arrows in FIG. 6A, this makes it possible for the second light guiding member 52 to collect the entering light having a green wavelength at the color filter 40g and the photoelectric conversion section 12 in the pixel Pg. The photoelectric conversion section 12 in the pixel Pg is able to efficiently receive light having a green wavelength and perform photoelectric conversion.

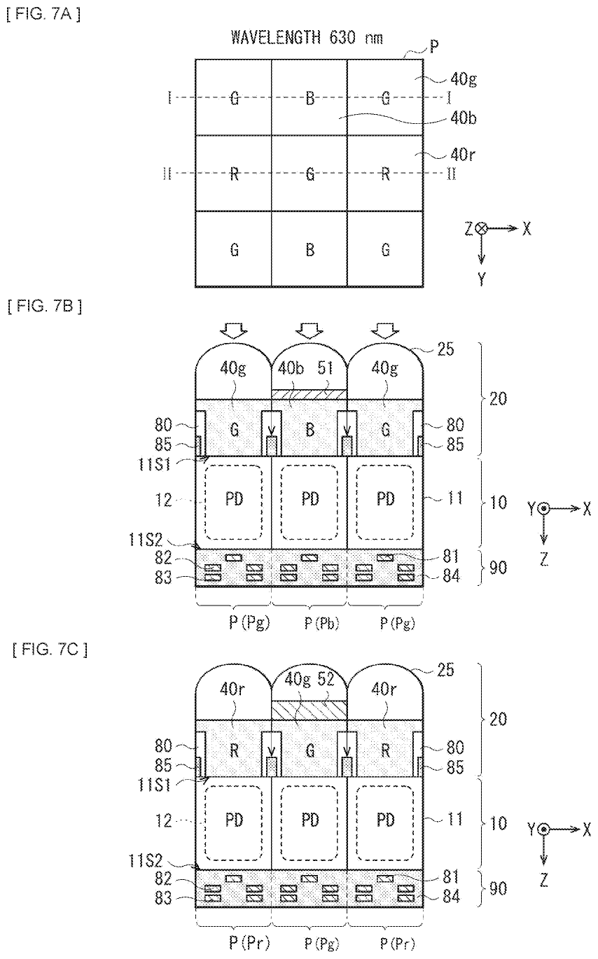

Next, with reference to FIG. 7, a case where light having a red wavelength range of 630 nm enters will be described. FIG. 7B illustrates a cross-sectional configuration in a line I-I direction illustrated in FIG. 7A. FIG. 7C illustrates a cross-sectional configuration in a II-II direction illustrated in FIG. 7A. In FIG. 7B, the light having a red wavelength, which enters the first light guiding member 51 via the lens section 25 from above, proceeds toward the color filter 40b or the light-shielding section 85 in the pixel Pb, to be absorbed by the blue color filter 40b or the light-shielding section 85. This makes it possible to prevent unnecessary light from leaking into a surrounding portion, suppressing generation of color mixing.

In FIG. 7C, the light having a red wavelength, which enters the second light guiding member 52 from above, proceeds to the color filter 40g or the light shielding section 85 in the pixel Pg, to be absorbed by the green color filter 40g or the light shielding section 85. This makes it possible to suppress generation of color mixing.

### [Workings and Effects]

The imaging device 1 according to the present embodiment includes a first filter (for example, the green color filter 40g) having a first refractive index for entering light and a first photoelectric conversion section (the photoelectric conversion section 12 in the pixel Pg) that performs photoelectric conversion on light transmitted through the first filter. In addition, the imaging device 1 includes a second filter (for example, the blue color filter 40b) that has a second refractive index lower than the first refractive index for entering light and is adjacent to the first filter, and a second photoelectric conversion section (the photoelectric conversion section 12 in the pixel Pb) that performs photoelectric conversion on light transmitted through the second filter. Furthermore, the imaging device 1 includes a first medium (for example, the same material as the lens section 25 in the pixel Pg) that is provided on an opposite side of the first photoelectric conversion section as viewed from the first filter and has a third refractive index for entering light, and a second medium (for example, the first light guiding member 51) that is provided on an opposite side of the second photoelectric conversion section as viewed from the second filter and has a fourth refractive index higher than the third refractive index for entering light.

In the imaging device 1, the first light guiding member 51 (or the second light guiding member 52) is provided on the color filter 40 having a lower refractive index of adjacent color filters 40. This makes it possible to suppress a decrease in light collection efficiency in the pixel P including a color filter 40 having a relatively low refractive index. It is possible to perform efficient light collection and improve quantum efficiency (QE). In addition, it is possible to suppress generation of color mixing.

Next, some modification examples of the present disclosure will be described. In the following, components similar to those in the above embodiment will be denoted the same reference numerals, and the description thereof will be omitted as appropriate.

### 2. Modification Examples

### 2-1. Modification Example 1

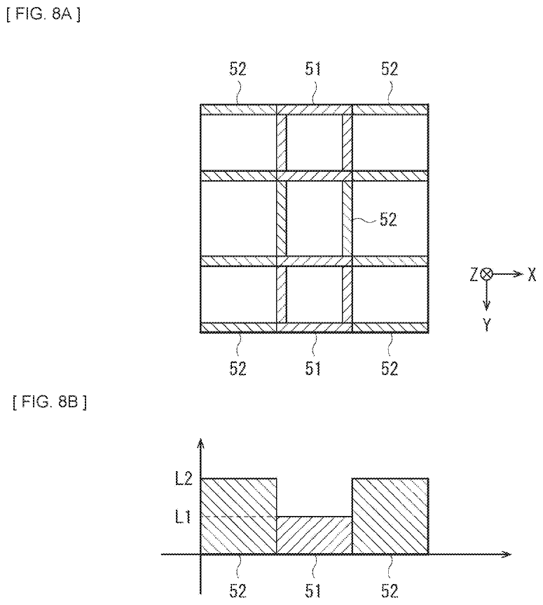

In the embodiment described above, some configuration examples of the first light guiding member 51 and the second light guiding member 52 have been described, but the configuration of the first light guiding member 51 and the second light guiding member 52 is not limited to this. FIG. 8A illustrates an configuration example of the imaging device 1 according to Modification Example 1.

For example, as illustrated in FIG. 8A, the first light guiding member 51 and the second light guiding member 52 may be provided to surround the photoelectric conversion section 12 or the color filter 40 in the pixel P. FIG. 8B illustrates an example of the film thickness of the first light guiding member 51 and the second light guiding member 52. In the case of the present modification example as well, the film thickness L2 of the second light guiding member 52 may be greater than the film thickness L1 of the first light guiding member 51. In the present modification example as well, it is possible to perform efficient light collection and improve quantum efficiency (QE). In addition, it is possible to suppress generation of color mixing.

### 2-2. Modification Example 2

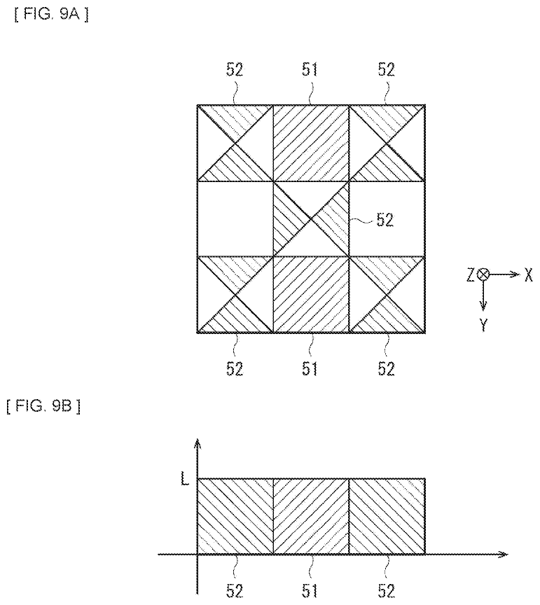

FIG. 9A illustrates an example of a planar configuration of the imaging device 1 according to Modification Example 2. FIG. 9B illustrates an example of the film thickness of the first light guiding member 51 and the second light guiding member 52 illustrated in FIG. 9A. In the present modification example, the first light guiding member 51 and the second light guiding member 52 are formed to allow the second light guiding member 52 to have a greater refractive index than the refractive index of the first light guiding member 51. In addition, the first light guiding member 51 and the second light guiding member 52 have an approximately equal film thickness. In the case of the present modification example as well, it is possible to obtain the same effect as the imaging device in the above embodiment.

### 2-3. Modification Example 3

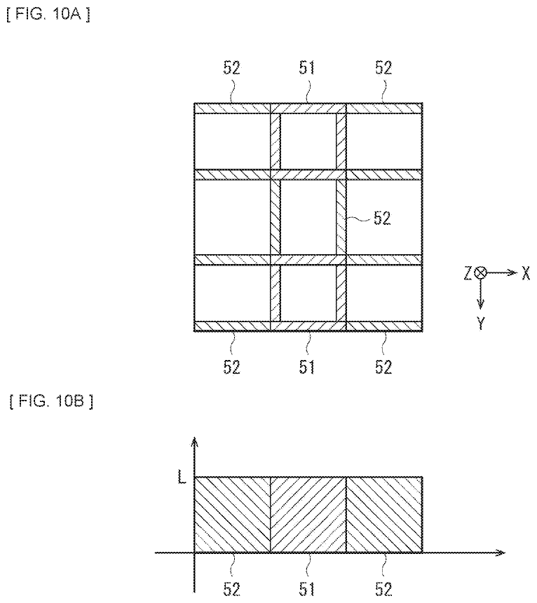

FIG. 10A illustrates an example of a planar configuration of the imaging device 1 according to Modification Example 3. FIG. 10B illustrates an example of the film thickness of the first light guiding member 51 and the second light guiding member 52 illustrated in FIG. 10A. As illustrated in FIG. 10A, the first light guiding member 51 and the second light guiding member 52 are provided in a grid pattern. The second light guiding member 52 has a refractive index greater than the refractive index of the first light guiding member 51. In addition, the first light guiding member 51 and the second light guiding member 52 have an approximately equal film thickness. In the case of the present modification example as well, it is possible to obtain the same effect as the imaging device in the above embodiment.

### 2-4. Modification Example 4

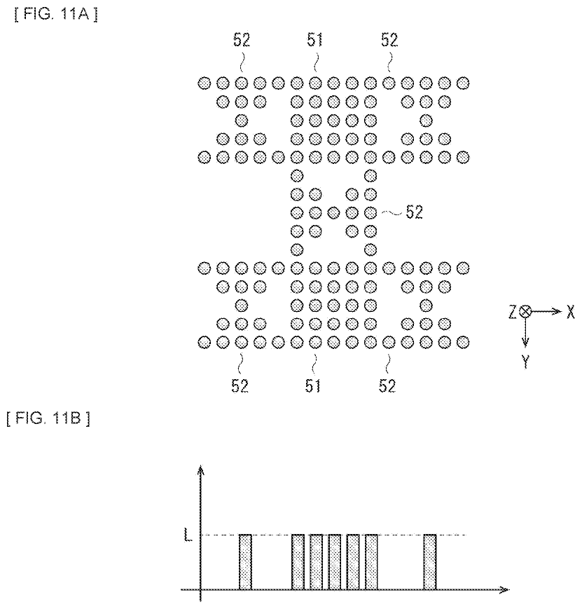

FIG. 11A illustrates an example of a planar configuration of the imaging device 1 according to Modification Example 4. FIG. 11B illustrates an example of the film thickness (height) of the first light guiding member 51 and the second light guiding member 52 illustrated in FIG. 11A.

The first light guiding member 51 and the second light guiding member 52 each include a plurality of structures. These structures are each a microscopic (minute) structure having a size equal to or less than a predetermined wavelength of entering light, for example, equal to or less than a wavelength of visible light. The structure has a refractive index higher than the refractive index of a surrounding medium. As the medium surrounding the structure, it is possible to give air (void), silicon oxide (SiOx), or the like. As illustrated in FIG. 11B, for example, the structure is a columnar (pillar-shaped) structure having a thickness (length) L in the Z-axis direction.

The first light guiding member 51 and the second light guiding member 52 have the microscopic structure described above, and due to a difference in refractive index between the microscopic structure and a periphery thereof, it is possible to change the travelling direction of entering light. It can also be said that the first light guiding member 51 and the second light guiding member 52 are ach a deflection section (deflection element) that deflects light using metamaterial (metasurface) technology.

The imaging device 1 according to the present modification example includes the first light guiding member 51 and the second light guiding member 52. The first light guiding member 51 and the second light guiding member 52 each include a microscopic structure and deflect entering light. In the present modification example as well, it is possible to expect the same effect as the imaging device in the above embodiment.

### 2-5. Modification Example 5

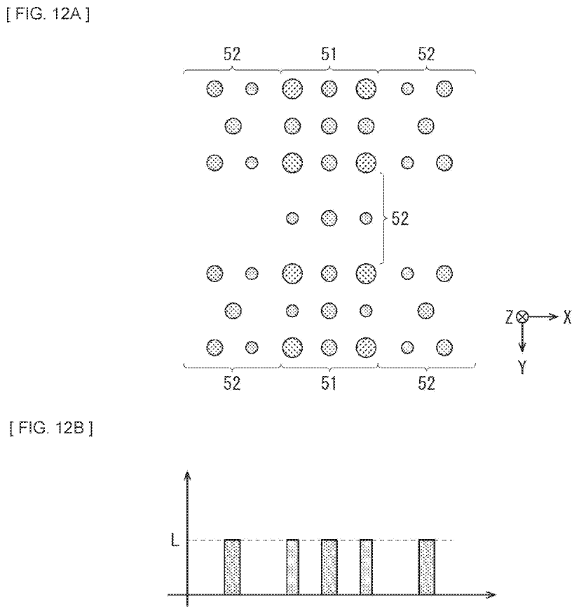

FIG. 12A illustrates an example of a planar configuration of the imaging device 1 according to Modification Example 5. FIG. 12B illustrates an example of the film thickness (height) of the first light guiding member 51 and the second light guiding member 52 illustrated in FIG. 12A. As in the case of FIGS. 11A and 11B, the first light guiding member 51 and the second light guiding member 52 are configured using a plurality of structures.

Each of the first light guiding member 51 and the second light guiding member 52 may include a plurality of microscopic structures each having a different shape, height, arrangement interval, and the like. For example, as in the examples illustrated in FIGS. 12A and 12B, the first light guiding member 51 and the second light guiding member 52 may include a plurality of columnar (pillar-shaped) structures each having a different diameter. In addition, for example, the first light guiding member 51 and the second light guiding member 52 may include a plurality of pillar-shaped structures each having a different height.

For example, the first light guiding member 51 and the second light guiding member 52 are configured using a plurality of structures each having a different diameter, height, and the like, to allow an amount of phase delay to gradually change depending on a position. In the imaging device 1 according to the present modification example, a lens (metamaterial lens) is configured using a plurality of structures each having a different diameter, height, and the like, making it possible to realize a phase gradient. It becomes possible to further improve color separation performance and light collection performance.

### 3. Application Example

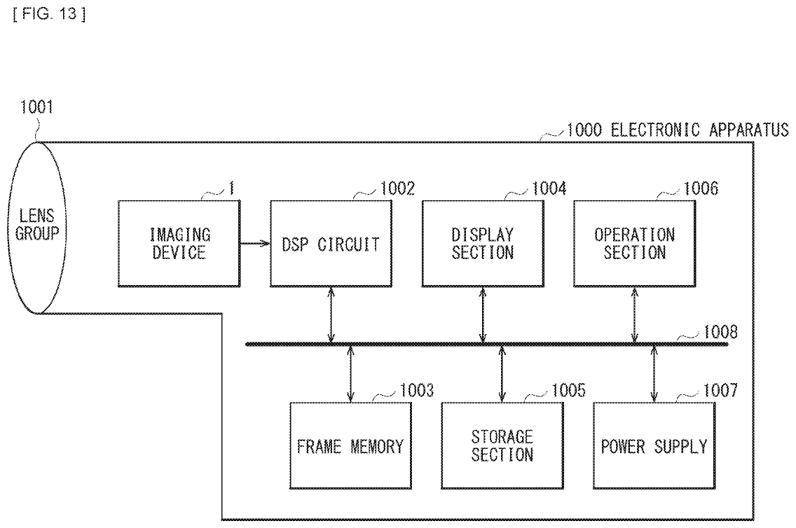

The imaging device 1 or the like described above is applicable to any type of electronic apparatus equipped with an imaging function, for example, a camera system such as a digital still camera or a video camera, a mobile phone having an imaging function, or the like. FIG. 13 illustrates a schematic configuration of an electronic apparatus 1000.

For example, the electronic apparatus 1000 includes a lens group 1001, an imaging device 1, a DSP (Digital Signal Processor) circuit 1002, a frame memory 1003, a display section 1004, a recording section 1005, an operation section 1006, and a power supply 1007, which are coupled with each other via a bus line 1008.

The lens group 1001 captures entering light (image light) from a subject and forms an image on an imaging surface of the imaging device 1. The imaging device 1 converts the quantity of the entering light, which is formed on the imaging surface by the lens group 1001, into an electrical signal on a pixel-by-pixel basis and supplies the electrical signal as a pixel signal to the DSP circuit 1002.

The DSP circuit 1002 is a signal processing circuit that processes a signal supplied from the imaging device 1. The DSP circuit 1002 outputs image data obtained by processing the signal from the imaging device 1. The frame memory 1003 temporarily holds, on a frame-by-frame basis, the image data processed by the DSP circuit 1002.

The display section 1004, for example, includes a panel-type display device such as a liquid crystal panel or an organic EL (Electro Luminescence) panel, and records image data of a moving picture or a still image captured by the imaging device 1 on a recording medium such as semiconductor memory or hard disk.

In accordance with an operation by a user, the operation section 1006 outputs an operation signal concerning various functions incorporated in the electronic apparatus 1000. The power supply 1007 supplies various power sources that serve as an operating power source for the DSP circuit 1002, the frame memory 1003, the display section 1004, the recording section 1005, and the operation section 1006, to these supply targets as appropriate.

### 4. Practical Applications

### (Practical Application to Mobile Body)

The technique of the present disclosure (the present technology) is applicable to various products. For example, the technique of the present disclosure may be realized as a device mounted on any type of mobile body such as a car, electric vehicle, hybrid electric vehicle, motorcycle, bicycle, personal mobility, airplane, drone, ship, or robot.

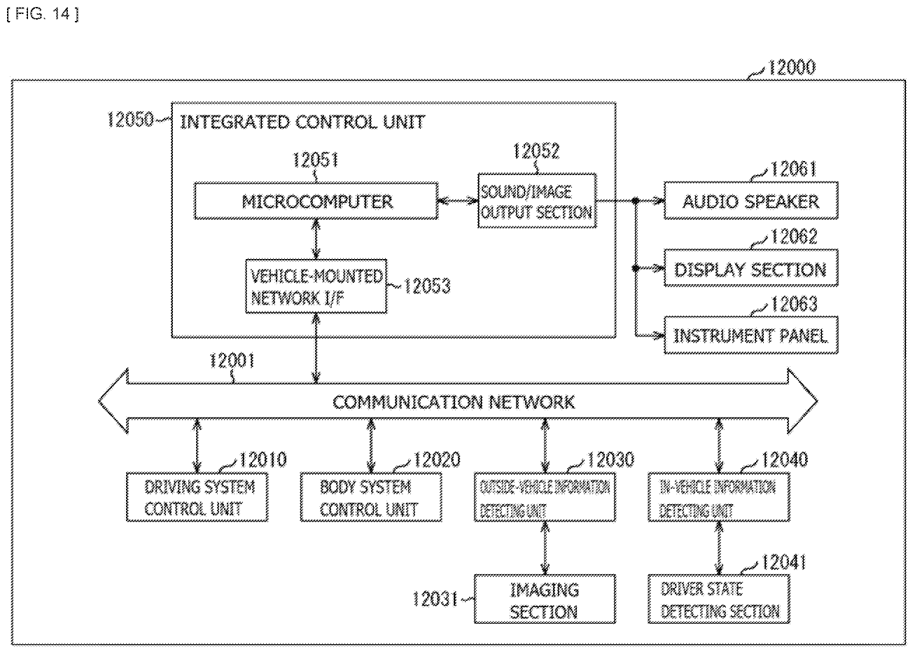

FIG. 14 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 14, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are illustrated as the output device. The display section 12062 may, for example, include at least one of an on-board display and a head-up display.

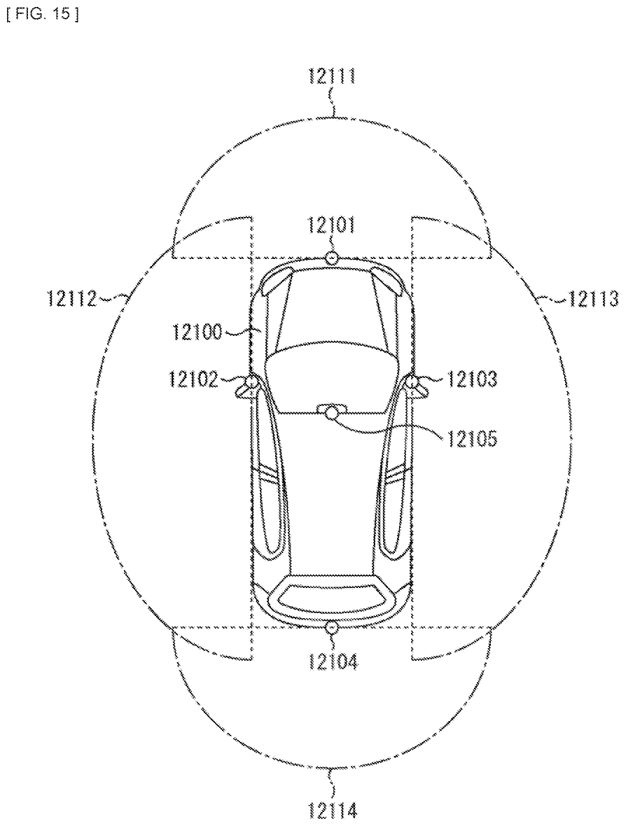

FIG. 15 is a diagram depicting an example of the installation position of the imaging section 12031.

In FIG. 15, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 15 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of a mobile body control system to which the technique of the present disclosure is applicable has been described above. Of the configuration described above, for example, the technique of the present disclosure is applicable to the imaging section 12031. Specifically, for example, it is possible to apply the imaging device 1 to the imaging section 12031. Application of the technique of the present disclosure to the imaging section 12031 makes it possible to obtain a high-resolution captured image with low noise, allowing for highly accurate control using the captured image in the mobile body control system.

### (Practical Application to Endoscopic Surgery System)

It is possible to apply the technique of the present disclosure (the present technology) to various products. For example, the technique of the present disclosure may be applied to an endoscopic surgery system.

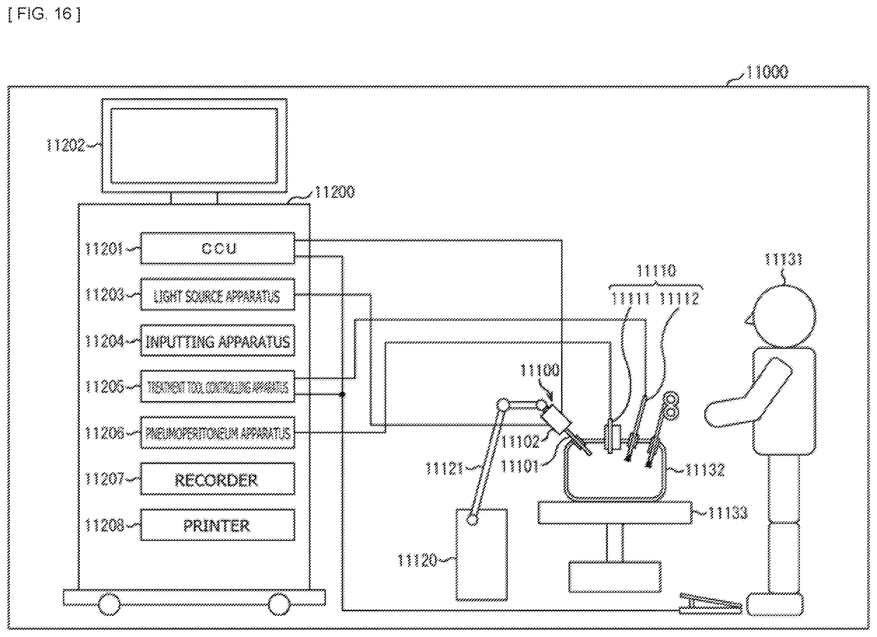

FIG. 16 is a view depicting an example of a schematic configuration of an endoscopic surgery system to which the technology according to an embodiment of the present disclosure (present technology) can be applied.

In FIG. 16, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

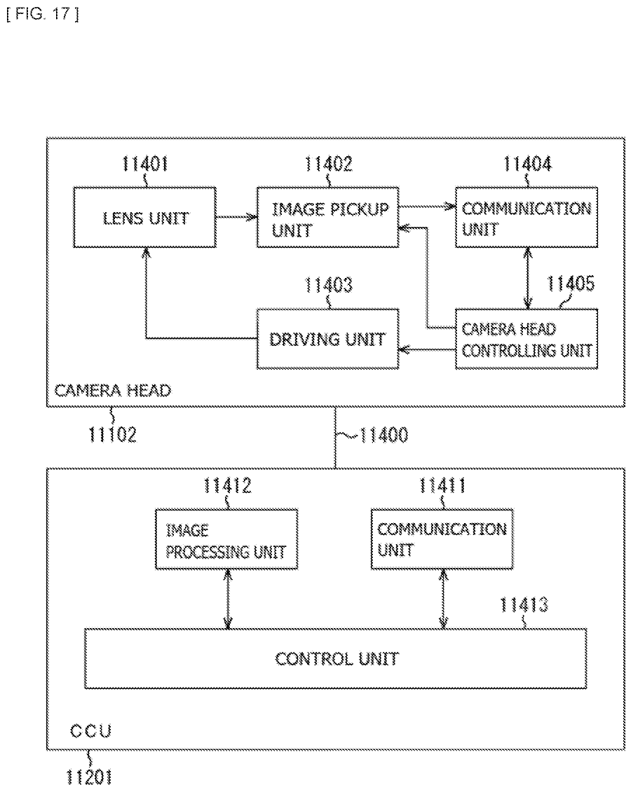

FIG. 17 is a block diagram depicting an example of a functional configuration of the camera head 11102 and the CCU 11201 depicted in FIG. 16.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of an endoscopic surgery system to which the technique of the present disclosure is applicable has been described above. Of the configuration described above, for example, the technique of the present disclosure is preferably applicable to the imaging section 11402 provided in the camera head 11102 in the endoscope 11100. Application of the technique of the present disclosure to the image capturing section 11402 makes it possible to realize a high-sensitive image capturing section 11402, allowing for a high-definition endoscope 11100.

The present disclosure has been described above with reference to an embodiment, modification and application examples, and practical applications, but the present technique is not limited to the above embodiment, etc. and various modifications are possible. For example, the above modification examples have been described as those of the above embodiment, but it is possible to combine the configuration of each modification example as appropriate. For example, the present disclosure is not limited to a back-illuminated image sensor but is also applicable to a front-illuminated image sensor.

It is to be noted that effects described herein are merely illustrative and are not limitative, and may have other effects. In addition, the present disclosure may have the following configurations.

(1)

An imaging device including:
a first filter having a first refractive index for entering light:
a first photoelectric conversion section that performs photoelectric conversion on light transmitted through the first filter;
a second filter having a second refractive index lower than the first refractive index for entering light, the second filter being adjacent to the first filter;
a second photoelectric conversion section that performs photoelectric conversion on light transmitted through the second filter;
a first medium provided on an opposite side of the first photoelectric conversion section as viewed from the first filter, the first medium having a third refractive index for entering light; and
a second medium provided on an opposite side of the second photoelectric conversion section as viewed from the second filter, the second medium having a fourth refractive index higher than the third refractive index.
   (2)

The imaging device according to (1), in which
light having entered the second medium is sequentially transmitted through the second medium and the second filter, to subsequently enter the second photoelectric conversion section.
   (3)

The imaging device according to (1) or (2), in which
the second medium is provided to cover at least a portion of the second filter, the portion being adjacent to the first filter.
   (4)

The imaging device according to any one of (1) to (3), in which
the second filter has the second refractive index for light having a first wavelength out of the entering light, and
the first filter has the first refractive index for the light having the first wavelength, the first filter having a fifth refractive index for light having a second wavelength different from the first wavelength.
   (5)

The imaging device according to any one of (1) to (4), in which
the first filter is a filter that transmits light having a green wavelength range and the second filter is a filter that transmits light having a blue wavelength range, or
the first filter is a filter that transmits light having a red wavelength range and the second filter is a filter that transmits light having a green wavelength range.
   (6)

The imaging device according to (4), including:
a third filter having a six refractive index for the light having the second wavelength, the third filter being adjacent to the first filter, and the six refractive index being higher than the fifth refractive index;
a third photoelectric conversion section that performs photoelectric conversion on light transmitted through the third filter; and
a third medium provided on an opposite side of the first photoelectric conversion section as viewed from the first filter, the third medium having a seventh refractive index higher than the sixth refractive index for entering light.
   (7)

The imaging device according to (6), in which
the third medium is provided to cover at least a portion of the first filter, the portion being adjacent to the third filter.
   (8)

The imaging device according to (6) or (7), in which
the third medium is adjacent to the first medium on the opposite side of the first photoelectric conversion section as viewed from the first filter.
   (9)

The imaging device according to any one of (6) to (8), in which
the first filter is a filter that transmits light having a green wavelength range,
the second filter is a filter that transmits light having a blue wavelength range, and
the third filter is a filter that transmits light having a red wavelength range.
   (10)

The imaging device according to any one of (6) to (9), in which
the third medium has a thickness greater than a thickness of the second medium in a light entering direction.
   (11)

The imaging device according to any one of (6) to (10), in which
the third medium has a refractive index higher than a refractive index of the second medium.
   (12)

The imaging device according to any one of (6) to (11), in which
each of the second medium and the third medium has a structure having a size equal to or less than a wavelength of entering light.

This application claims priority based on Japanese Patent Application No. 2021-129694 filed on Aug. 6, 2021 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof.

1. An imaging device comprising:
a first filter having a first refractive index for entering light;
a first photoelectric conversion section that performs photoelectric conversion on light transmitted through the first filter;
a second filter having a second refractive index lower than the first refractive index for entering light, the second filter being adjacent to the first filter;
a second photoelectric conversion section that performs photoelectric conversion on light transmitted through the second filter;
a first medium provided on an opposite side of the first photoelectric conversion section as viewed from the first filter, the first medium having a third refractive index for entering light; and
a second medium provided on an opposite side of the second photoelectric conversion section as viewed from the second filter, the second medium having a fourth refractive index higher than the third refractive index.

2. The imaging device according to claim 1, wherein
light having entered the second medium is sequentially transmitted through the second medium and the second filter, to subsequently enter the second photoelectric conversion section.

3. The imaging device according to claim 1, wherein
the second medium is provided to cover at least a portion of the second filter, the portion being adjacent to the first filter.

4. The imaging device according to claim 1, wherein
the second filter has the second refractive index for light having a first wavelength out of the entering light, and
the first filter has the first refractive index for the light having the first wavelength, the first filter having a fifth refractive index for light having a second wavelength different from the first wavelength.

5. The imaging device according to claim 1, wherein
the first filter is a filter that transmits light having a green wavelength range and the second filter is a filter that transmits light having a blue wavelength range, or
the first filter is a filter that transmits light having a red wavelength range and the second filter is a filter that transmits light having a green wavelength range.

6. The imaging device according to claim 4, comprising:
a third filter having a six refractive index for the light having the second wavelength, the third filter being adjacent to the first filter, and the six refractive index being higher than the fifth refractive index;
a third photoelectric conversion section that performs photoelectric conversion on light transmitted through the third filter; and
a third medium provided on an opposite side of the first photoelectric conversion section as viewed from the first filter, the third medium having a seventh refractive index higher than the sixth refractive index for entering light.

7. The imaging device according to claim 6, wherein
the third medium is provided to cover at least a portion of the first filter, the portion being adjacent to the third filter.

8. The imaging device according to claim 6, wherein
the third medium is adjacent to the first medium on the opposite side of the first photoelectric conversion section as viewed from the first filter.

9. The imaging device according to claim 6, wherein
the first filter is a filter that transmits light having a green wavelength range,
the second filter is a filter that transmits light having a blue wavelength range, and
the third filter is a filter that transmits light having a red wavelength range.

10. The imaging device according to claim 6, wherein
the third medium has a thickness greater than a thickness of the second medium in a light entering direction.

11. The imaging device according to claim 6, wherein
the third medium has a refractive index higher than a refractive index of the second medium.

12. The imaging device according to claim 6, wherein
each of the second medium and the third medium has a structure having a size equal to or less than a wavelength of entering light.
